(19) United States
(12) Patent Application Publication
(10) Pub. No.: US 2019/0221492 A1
(43) Pub. Date: Jul. 18, 2019

(54) PROCESSOR SOCKET ASSEMBLY AND CARRIER THEREOF

(71) Applicant: Jentech Precision Industrial Co., LTD., Taoyuan City (TW)

(72) Inventors: Chang-Chi YEH, TAOYUAN CITY (TW); Wei-Han HUANG, TAOYUAN CITY (TW)

(21) Appl. No.: 16/247,594

(22) Filed: Jan. 15, 2019

(30) Foreign Application Priority Data
Jan. 16, 2018 (TW) 107101586

(51) Int. Cl. H01L 23/32; H01R 12/70; H01R 13/635

(52) U.S. Cl. CPC H01L 23/32; H01R 13/635; H01R 12/7076; H01R 12/7058

(57) ABSTRACT

A processor socket assembly includes a processor socket, a base frame, a guide member and a carrier. The processor socket is located on a circuit board. The base frame surrounds the processor socket. The guide member is pivoted to an edge of the bottom frame to be rotatable relative to the processor socket, and the guide member has a slot. The carrier detachably engages the slot of the guide member after being combined with a processor and is capable of being rotated with the guide member.

### CROSS-REFERENCE TO RELATED APPLICATION

This application claims priority to Taiwan Application Serial Number 107101586, filed Jan. 16, 2018, which is herein incorporated by reference in its entirety.

### BACKGROUND

### Field of Invention

The present disclosure relates to an electrical connector, and more particularly, to a processor socket assembly.

### Description of Related Art

With the advancement of semiconductor manufacturing processes, processors have moved toward low-power and multi-core needs while a number of processor signal pins is increased at the same time, e.g., for computation servers.

Therefore, the processor socket on the motherboard also needs a large number of electrical connector pins to mount a corresponding processor such that the area occupied by the processor socket is continuously enlarged, and the risk for the electrical connector pins being deformed due to external forces is relatively high.

How to reduce the exposure time of pins in a processor socket and reduce the chance of external force intrusion is one of the concerns for associated manufacturers in this field.

### SUMMARY

In one or more embodiments, a carrier used with a processor has a positioning member configured to be detachably coupled with a guide member of a processor socket assembly, and the positioning member includes a latch.

In one or more embodiments, the carrier further includes a metal inner frame and an insulation coating.

In one or more embodiments, the positioning member is located on the insulation coating.

In one or more embodiments, the metal inner frame includes a pair of corners each of which has a fastener.

In one or more embodiments, a processor socket assembly includes a processor socket disposed on a circuit board, a base frame surrounding the processor socket and disposed on the circuit board, a guide member pivotally connected to an edge of the base frame and configured to swivel relative to the processor socket, and a carrier assembled with a processor and detachably coupled with a slot of the guide member, and configured to swivel together with the guide member.

In one or more embodiments, the base frame includes a pair of extension parts, and the guide member is pivotally connected between the pair of extension parts.

In one or more embodiments, the processor socket assembly further includes a shaft and torsion spring, at least part of the torsion spring is arranged around the shaft, and a middle part of the torsion spring contacts the guide member.

In one or more embodiments, the guide member includes a concave section to be contacted by the middle part of the torsion spring.

In one or more embodiments, each extension part has a vertical rib, the guide member has two block members at two side edges respectively, each block member is in contact with each vertical rib when the guide member is swiveled to an upright position relative to the circuit board.

In one or more embodiments, the processor socket assembly further includes a protection lid which has first corners that have at least a position hole, the base frame has second corners that have at least a position pin, and the position pin engages the position hole when the protection lid is covered over the processor socket.

In sum, the processor socket assembly herein has a guide member which is pivotally connected to the base frame and rotatable relative to processor socket. The processor socket assembly further includes a processor carrier to hold the processor as a combination, which can be detachably coupled to a slot of the guide member. After removing a protection lid to expose a processor socket, a combination of the processor carrier, the processor and the guide member can be swiveled down onto the processor socket rapidly and accurately such that the signal pins within the processor socket are exposed within a very short time to avoid deforming or damaging risks due to an external force intrusion.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a perspective view of a processor socket assembly according to one embodiment of the present disclosure;

FIG. 1A illustrates an enlarged view of a guide member in FIG. 1;

FIG. 2 illustrates a perspective view of a processor socket assembly according to another embodiment of the present disclosure;

FIGS. 3A and 3B illustrate top and bottom views of a processor carrier according to one embodiment of the present disclosure;

FIG. 4 illustrates a disassembled view of the processor carrier in FIG. 3; and

FIGS. 5A-5G illustrate views for a series of steps to mount a processor onto a processor socket on a circuit board according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The present invention provides a solder manufacturing method that uses a temperature curve to determine solder quality and improve solder quality. The soldering process method includes a pre-training method and a subsequent inspection or soldering improvement method.

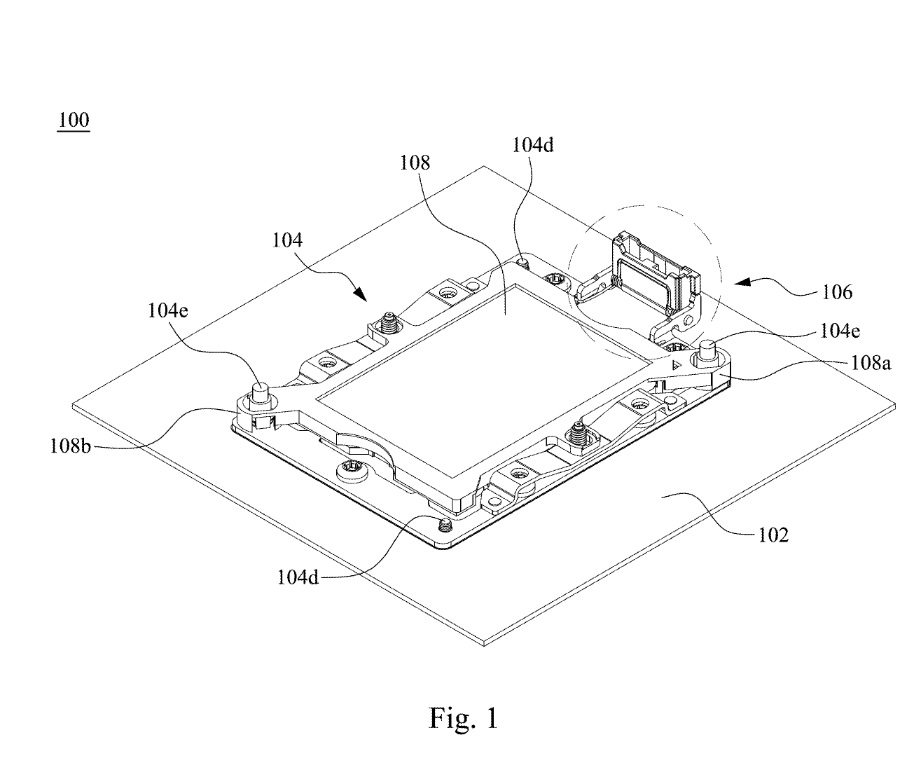

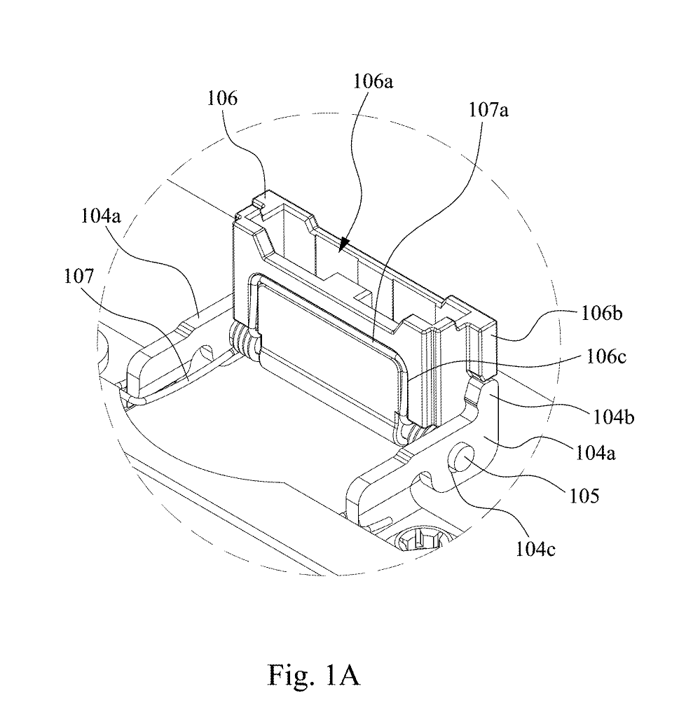

The present invention provides a processor socket assembly to be mounted onto a circuit board so as to carry and secure an associated processor and provides an electrical connection between the circuit board and the processor. Embodiments and usages for the processor socket assembly are discussed with FIGS. 1-5.

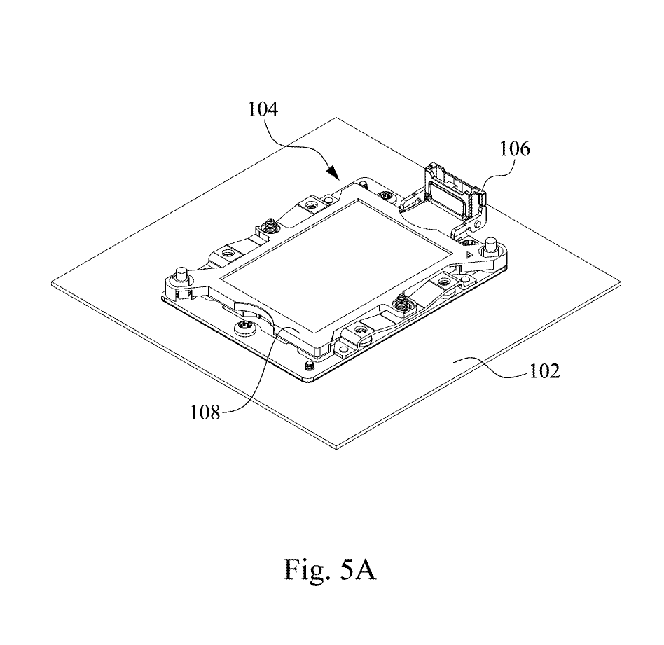

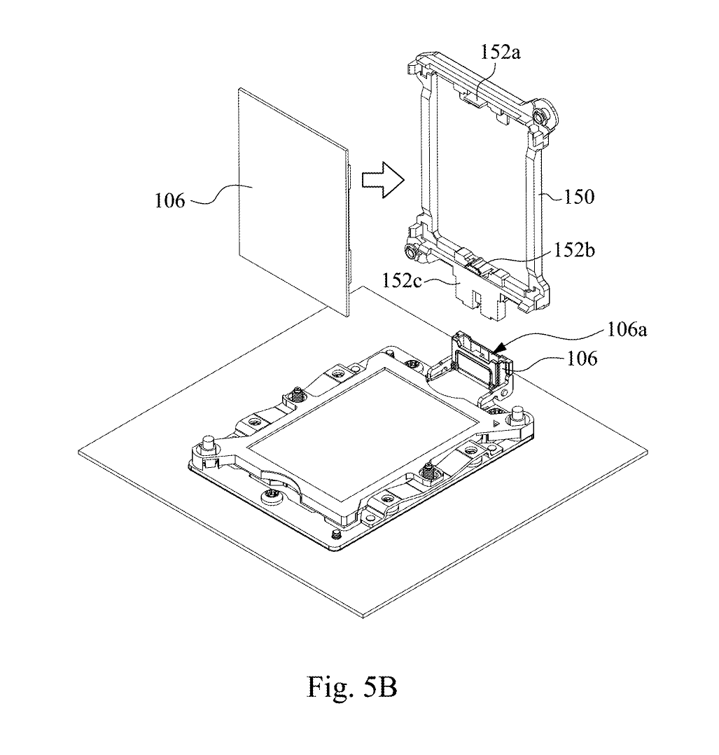

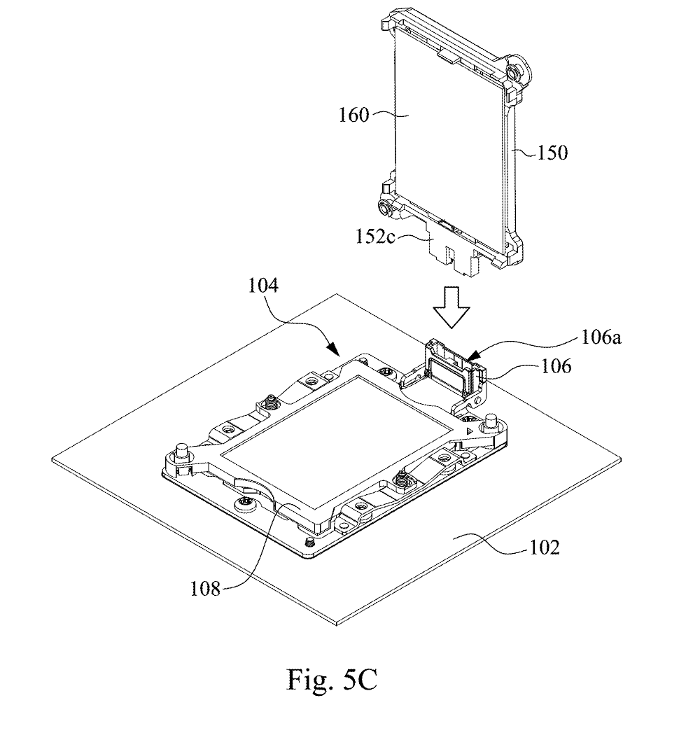

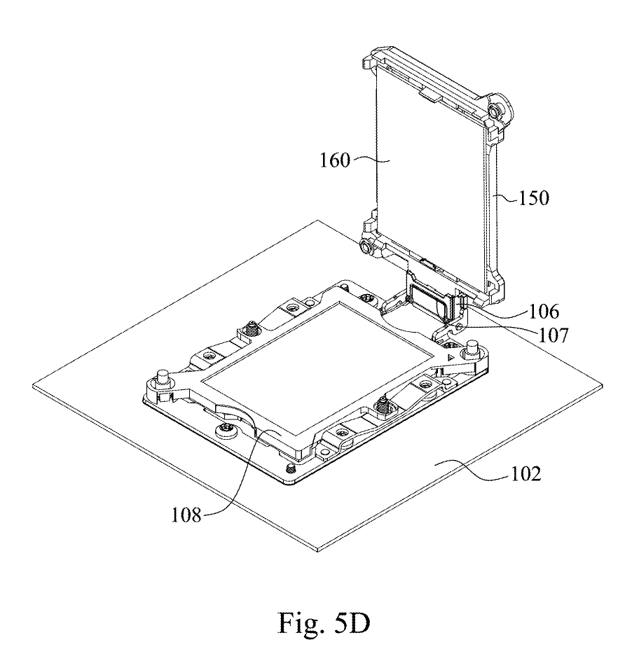

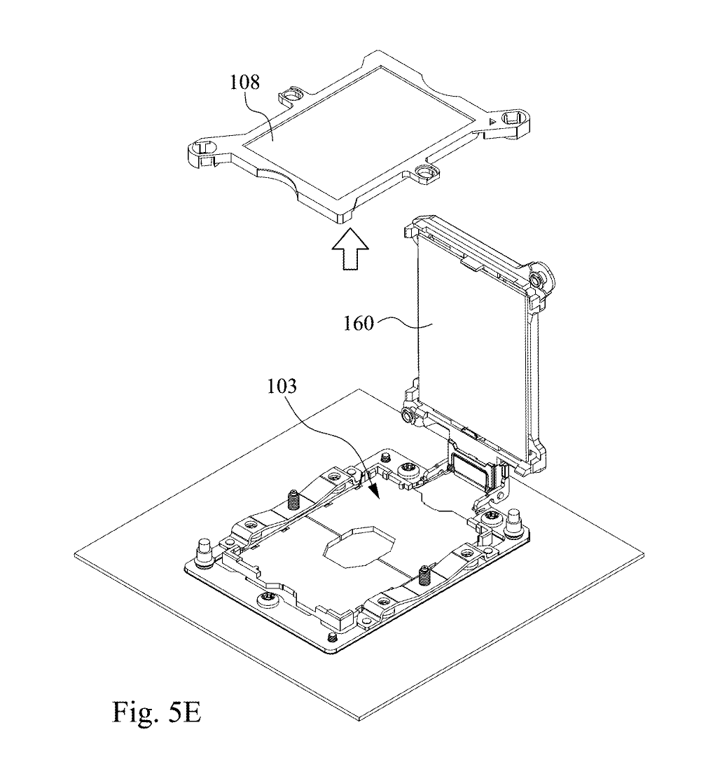

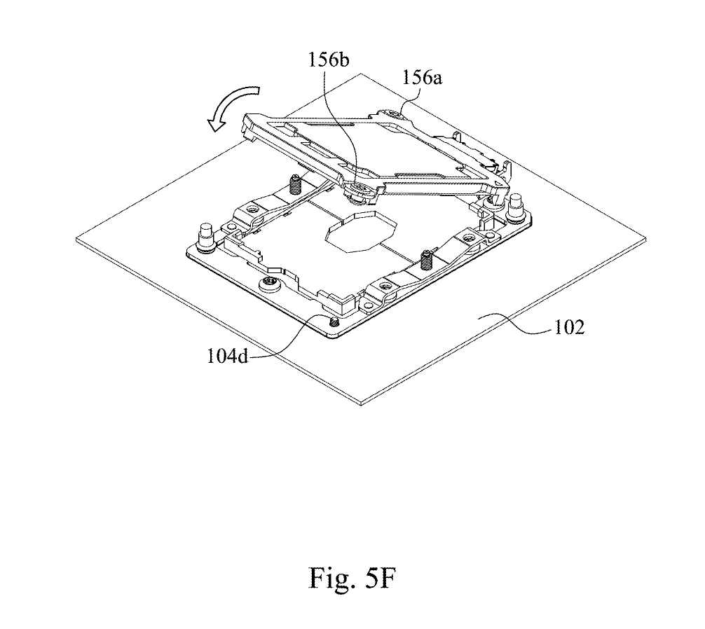

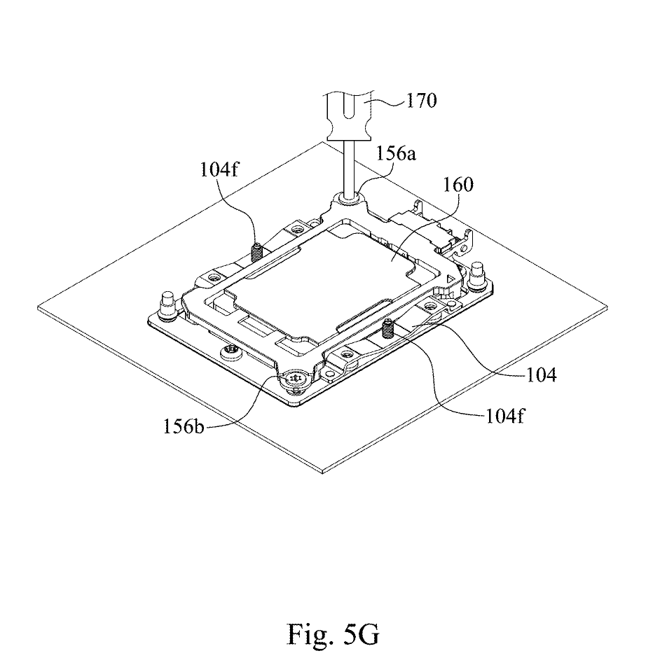

Reference is made to FIGS. 1 and 1A. FIG. 1 illustrates a perspective view of a processor socket assembly according to one embodiment of the present disclosure, and FIG. 1A illustrates an enlarged view of a guide member in FIG. 1. The processor socket assembly 100 includes a processor socket 103 (referring to FIG. 5E, the processor socket 103 is located under protection lid 108), a base frame 104 and a guide member 106. The processor socket 103 and the base frame 104 are both installed on to the circuit board 102, and the base frame 104 surrounds the processor socket 103. The guide member 106 is pivotally coupled to an edge of the base frame 104 and capable of being swiveled or rotated relative to the processor socket 103. The guide member 106 also has a concave slot 106a.

An edge of the base frame 104 has a pair of extension parts 104a allowing the guide member 106 to be pivotally between two extension parts 104a. A pivot shaft 105 is inserted through the two extension parts 104 via their pivot holes 104c such that the guide member 106 can be pivotally coupled between extension parts 104a. In other embodiments, the extension part may be single one instead of two, and the guide member may be pivotally coupled to an end portion of the extension part.

The processor socket assembly 100 further includes a torsion spring 107, and part of the torsion spring 107 is arranged around the pivot shaft 105 and a middle part 107a of the torsion spring 107 is in contact with a sidewall of the guide member 106. The guide member 106 further includes a concave section 106c to accommodate the middle part 107a of the torsion spring 107. In other embodiments, at least a potion (not limited to the middle part) of the torsion spring contacts the guide member 106, but the guide member 106 does not include a concave section to receive the torsion spring.

An end portion of each extension part 104a has a vertical rib 104b, and the guide member 106 has block members 106b at two opposite sides. When the guide member 106 is swiveled to an upright position relative to the circuit board 102, a bottom surface of the block member 106b contacts a top surface of the vertical rib 104b so as to prevent the guide member 106 with a combination of a processor carrier 150 and a processor 160 falling away from the processor socket 103. The guide member 106 supported by the vertical ribs 104b of the two extension parts 104a and a torsion force of the torsion spring 107 maintain the upright position relative to the circuit board 102. The upright position of the guide member 106 may not be perpendicular to the circuit board 102, but forms an included angle, e.g., 45 or 60 degrees, with the circuit board 102.

Before removing the protection lid 108 covered over the processor socket, its position holes (108a, 108b) at corners are engaged by position pins 104e of the base frame 104 to secure protection lid 108.

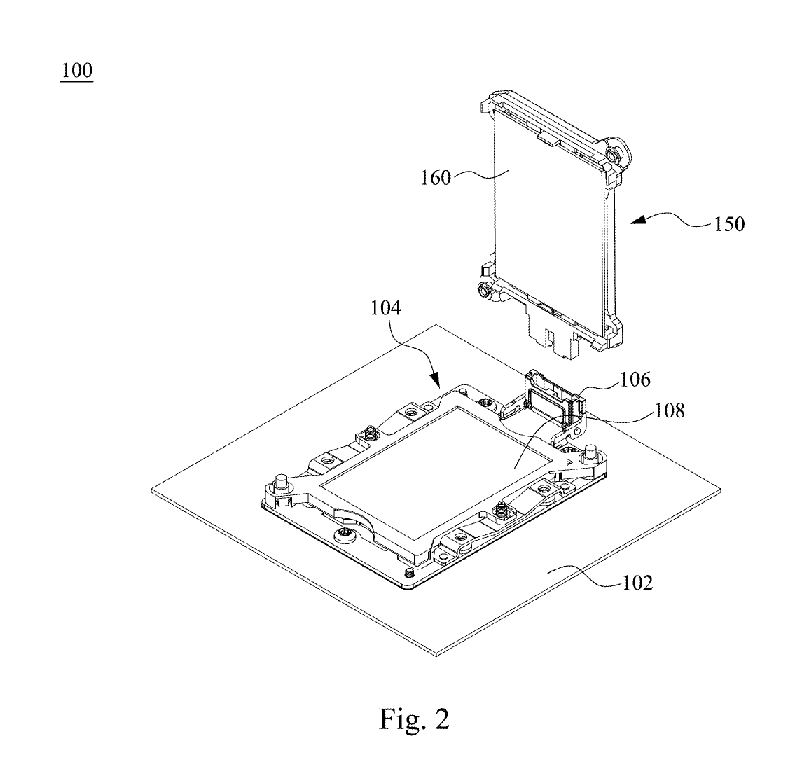

Reference is made to FIG. 2, which illustrates a perspective view of a processor socket assembly according to another embodiment of the present disclosure. The processor socket assembly 100 further includes a processor carrier 150. The processor carrier 150 is detachably coupled to the guide member 106, and swiveled or rotated together with the guide member 106 relative to processor socket 103 in order to facilitate a safe installing or uninstalling of the processor 160 to or from the processor socket.

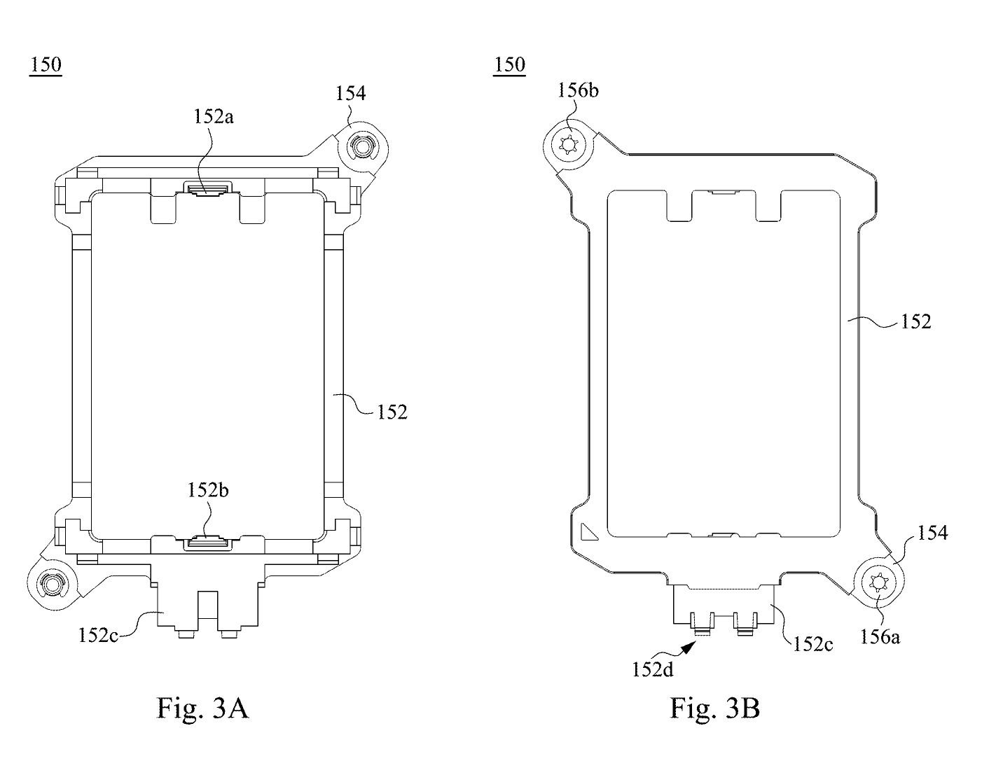

Reference is made to FIGS. 3A and 3B, which illustrate top and bottom views of a processor carrier 150 according to one embodiment of the present disclosure. The detachable processor carrier 150 can be assembled with an associated processor not in situ, i.e., away from the processor socket 103 and installed onto the guide member 106. The processor carrier 150 includes a metal inner frame 154 and an insulation coating 152. In this embodiment, the insulation coating 152 is formed over the metal inner frame 154 by an injection molding process. The metal inner frame 154 provides an overall required strength for the processor carrier 150 to avoid deformation of the processor carrier 150.

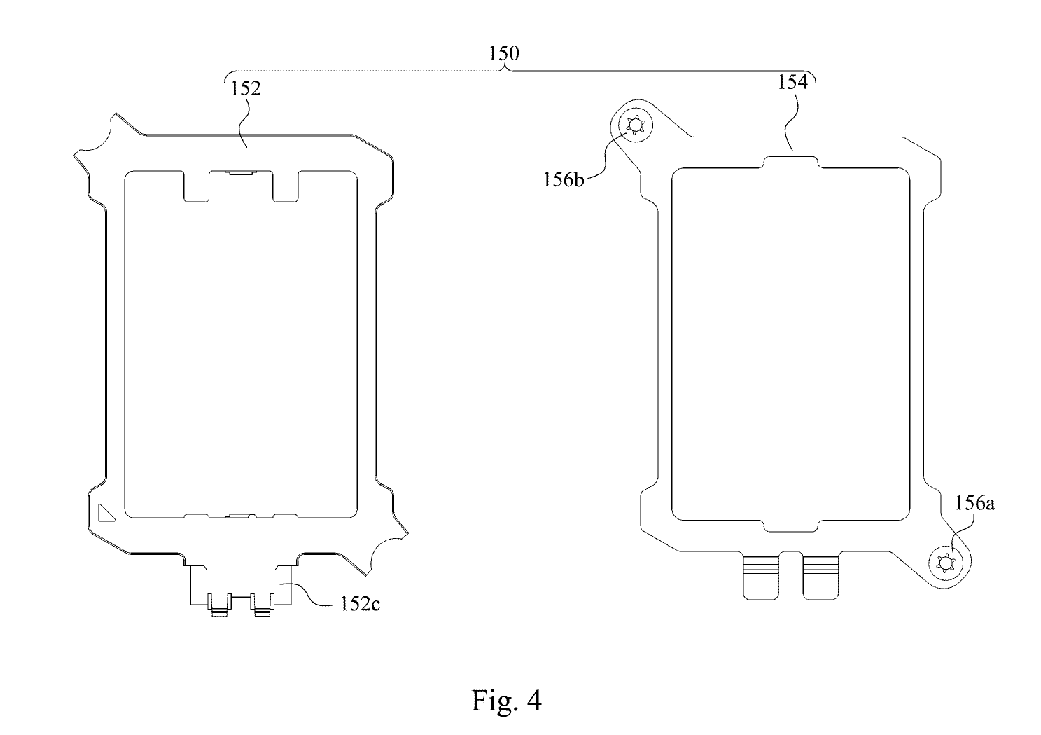

Reference is made to FIG. 4, which illustrates a disassembled view of the processor carrier in FIG. 3. As described, the processor carrier 150 includes a metal inner frame 154 and an insulation coating 152. The insulation coating 152 has a positioning member 152c that is inserted into the slot 106a of the guide member 106 (also referring to FIG. 1A), and its end portion has a look latch 152d to retain within the slot 106a of the guide member 106 (referring to FIG. 3B) against being pulled out. The metal inner frame 154 has a pair of corners, each of which has a fastener (156a or 156b). In other embodiments, the metal inner frame may have one, three or four fasteners on its corners.

Reference is made to FIGS. 5A-5G, which illustrate views for a series of steps to mount a processor onto a processor socket on a circuit board according to one embodiment of the present disclosure.

In FIGS. 5A and 5B, the processor carrier 150 is pulled from the guide member 106 and then assembled with a processor 160. In this embodiment, the processor carrier 150 has an upper retainer 152a and a lower retainer 152b to securely hold two edges of the processor 160.

In FIGS. 5C and 5D, after the processor carrier 150 is combined with the processor 160, a combination thereof is inserted onto the slot 106a of the guide member 106. At this moment, a combination of the processor carrier 150, processor 160 and the guide member 106 is supported by the two extension parts 104a and against by a torsion force of the torsion spring 107 so as to main the upright position relative to the circuit board 102 as previously discussed.

In FIGS. 5E and 5F, after removing the protection lid 108 to expose the processor socket 103 underneath, a force is applied against the torsion spring 107 to swivel down the combination of the processor carrier 150, processor 160 and the guide member 106 such that is moved and aligned to processor socket 103 to be accurately mounted onto the processor socket 103. Due to a short time gap between removing the protection lid 108 and the processor 160 mounted onto the processor socket 103 benefitted from the combination of the processor carrier 150, processor 160 and the guide member 106, the risk for deforming the electrical connector pins within processor socket 103 due to external forces is effectively reduced. And, the guide member 106 and the processor carrier 150 are capable of guiding the processor 160 to be accurately mounted onto the processor socket 103.

In FIG. 5G, after the processor 160 is mounted onto the processor socket 103, a screwdriver 170 is used to rotate the first fasteners (156a, 156b) to engage into second fasteners 104d. The base frame 104 may further include other fasteners 104 to secure an additional heat sink to contact a top surface of the processor 160. The first fastener and the second fastener are mutually lockable male and female fasteners.

In sum, the processor socket assembly herein has a guide member which is pivotally connected to the base frame and rotatable relative to processor socket. The processor socket assembly further includes a processor carrier to hold the processor as a combination, which can be detachably coupled to a slot of the guide member. After removing a protection lid to expose a processor socket, a combination of the processor carrier, the processor and the guide member can be swiveled down onto the processor socket rapidly and accurately such that the signal pins within the processor socket are exposed within a very short time to avoid deforming or damaging risks due to an external force intrusion.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A carrier used with a processor, the carrier comprising a positioning member configured to be detachably coupled with a guide member of a processor socket assembly, and the positioning member comprising a latch.

2. The carrier of claim 1, further comprising a metal inner frame and an insulation coating.

3. The carrier of claim 2, wherein the positioning member is disposed on the insulation coating.

4. The carrier of claim 2, wherein the metal inner frame comprises a pair of corners each having a fastener.

5. A processor socket assembly comprising:
a processor socket disposed on a circuit board;
a base frame surrounding the processor socket and disposed on the circuit board;
a guide member pivotally connected to an edge of the base frame and configured to swivel relative to the processor socket, the guide member having a slot; and
the carrier of claim 1 assembled with a processor and detachably coupled with the slot of the guide member, and configured to swivel together with the guide member.

6. The processor socket assembly of claim 5, wherein the base frame comprises a pair of extension parts, and the guide member is pivotally connected between the pair of extension parts.

7. The processor socket assembly of claim 5 further comprising a shaft and a torsion spring, at least part of the torsion spring is disposed around the shaft, and a middle part of the torsion spring contacts the guide member.

8. The processor socket assembly of claim 7, wherein the guide member comprises a concave section to be contacted by the middle part of the torsion spring.

9. The processor socket assembly of claim 8, wherein each extension part has a vertical rib, the guide member has two block members at two side edges respectively, each block member is in contact with the vertical rib when the guide member is swiveled to an upright position relative to the circuit board.

10. The processor socket assembly of claim 5 further comprising a protection lid having first corners that have at least a position hole, the base frame having second corners that have at least a position pin, and the position pin engages the position hole when the protection lid is covered over the processor socket.
